(19) United States
(12) Patent Application Publication
(10) Pub. No.: US 2015/0042195 A1
(43) Pub. Date: Feb. 12, 2015

(54) CORONA SHIELD MATERIAL FOR AN ELECTRIC MACHINE

(71) Applicant: SIEMENS AKTIENGESELLSCHAFT, München (DE)

(72) Inventors: Mario Brockschmidt, Essen (DE); Stefan Kempen, Arnsberg (DE); Friedhelm Pohlmann, Essen (DE); Guido Schmidt, Leichlingen (DE)

(21) Appl. No.: 14/388,908

(22) PCT Filed: Mar. 18, 2013
(86) PCT No.: PCT/EP2013/055512

§ 371 Date: Sep. 29, 2014

(30) Foreign Application Priority Data
Mar. 28, 2012 (EP) 12161774.0

(51) Int. Cl. H02K 3/42; H01B 1/24; H05K 9/00

(52) U.S. Cl. CPC H02K 3/42; H05K 9/0079; H01B 1/24
USPC 310/196; 252/510; 252/511; 252/516; 428/413; 428/423.1

(57) ABSTRACT

A corona shield material (22) for producing a corona shield protective layer (16, 17) for an electric machine (1). The corona shield material (22) contains an initially flowable matrix material (22) which can be cured in a curing reaction to form a solid. The corona shield material (22) further contains a photosensitive initiator (24) which can be transformed by electromagnetic radiation (25) into a reactive state triggering the curing reaction. The corona shield material (22) further contains at least one electrically conductive filler (25) in particulate form.

The invention relates to a corona shield material for producing a corona shield layer for an electric machine.

The term “electric machine” is used generally to denote an energy transducer which converts between electrical and mechanical energy, namely an electric motor or generator. An electric machine of this kind customarily comprises a stationary stator and a rotating rotor. The electric machine is in particular a turbogenerator, which is used in a power station for converting mechanical energy into electrical energy.

A turbogenerator is at present usually realized in the form of a three-phase AC synchronous machine comprising a solid two-pole or four-pole rotor. The power range of a turbogenerator of this kind ranges typically from approximately 20 MVA to approximately 2000 MVA.

The stator of a customary synchronous generator comprises a multiplicity of so-called stator windings, in which an AC voltage is induced by inductive interaction with the rotating rotor, to which a constant current is applied. The stator windings are accommodated in a so-called laminate stack. This stack serves among other things for guiding and intensifying the magnetic field. In order to reduce losses as a result of eddy currents, the entire laminate stack is constructed from thin laminations which are insulated from one another. The stator windings consist of a multiplicity of bars, whose respective central pieces (the so-called “active part”) are inserted into slots in the laminate stack. The individual bars emerge at the so-called “end winding” in involute form from the slots. There, the individual bars are interconnected (i.e., contacted with one another) to form the stator winding.

The bars or bar regions lying within the laminate stack are at a high electrical potential and are therefore insulated from one another, and also from the grounded laminate stack, by a principal insulating layer.

In order to avoid partial discharges at operating voltages of a few kV, the principal insulating layer is customarily shielded from cavities and detachments by an inner and an outer conducting layer (inner potential grading, IPG, and outer corona shielding, OCS). The electrical field strength is taken down in the principal insulating layer starting from the IPG in a radial direction right to the OCS.

The outer corona shield customarily ends in the exit region in which the respective bar emerges from the corresponding slot, whereas the principal insulating layer is continued outside the slot. In relation to the electrical strength, this arrangement represents a critical point, since a boundary layer forms between the principal insulating layer, which is present in a solid aggregate state, and a surrounding gaseous fluid (usually air or hydrogen).

Owing to a dielectric separation plane, resulting therefrom, between the principal insulation and the fluid, a typical sliding arrangement is produced, which as well as a purely radial field component, of the kind that occurs in the region of the laminate stack, also has a field component which is tangential (that is, which extends within the separation plane, but in particular somewhat parallel to the longitudinal extent of the conductor).

Because of the low electrical strength of the air, even a comparatively small voltage may be accompanied by the onset of a partial discharge, caused by the local tangential field strength increase (approximately 0.64 kV/mm for a clean surface), which in the case of a further increase in the voltage may widen into creeping discharges along the surface of the insulating material, or even to electrical breakdown (i.e., a conductor/ground short-circuit). This critical loading occurs in particular during the testing of the generator, since for testing purposes the generator is regularly operated up to the load limit. Over the long term, the insulating material is destroyed by the development of creeping discharges at the surface.

In the absence of protective mechanisms, the greatest field strength here occurs at the end of the outer corona shield. It is therefore normally necessary to ensure field control at the end of the outer corona shield, and an increase in strength in the vicinity of the exposed principal insulating layer.

This is typically achieved through the production of what is called an overhang corona shield. Here, in order to suppress creeping discharges, it is common to use resistive potential gradings by means of semiconductor (i.e., weakly conducting) varnishes or tapes based primarily on silicon carbide or on other electrically semiconducting fillers. The aim of the potential grading is to even out the tangential potential reduction along the surface of the insulating material. A resistance per unit length that is voltage-dependent and location-dependent in the axial direction is produced for this purpose.

Not only the outer corona shield but also the overhang corona shield are customarily realized either by wrapping the principal insulating layer with electrically weakly conducting (OCS) or electrically semiconducting (OHCS) tapes or by applying an electrically conducting or semiconducting varnish, respecttively. As far as the OHCS is concerned, the wrapped turns or the individual coats may be implemented in different lengths, in order to achieve the locational dependence that is desired in each case for the electrical resistance. Furthermore, the individual plies may also be realized from different materials having different electrical resistance characteristics.

The tapes consist customarily of an electrically nonconductive backing material (e.g., nonwoven polyester, woven polyester or glass fabric) and a reactive resin (for example, epoxidized phenol novolaks, frequently accelerated by means of dicyan-diamine) in a pre-reacted stage (“bi-stage”), which is filled with an electrically (semi)conducting filler.

Conducting and semiconducting varnishes are typically solvent-based systems such as phenolic resins, which are in turn provided with conducting or semiconducting, or semiconductingly functionalized, fillers.

In this context, for an outer corona shield, for example, it is frequently graphite that is used as the filler. EP 1 118 086 B1 discloses an outer corona shield which comprises an inorganic filler coated with antimony-doped tin oxide.

For an overhang corona shield, for example, silicon carbide is used. The resulting electrical resistance of the tape is determined in this case by factors including the average grain size.

A disadvantage of aforementioned tapes is that for complete curing they require curing for about two hours at approximately 165° C. or up to 12 hours at 120° C. On account of their comparatively high solvent content, abovementioned varnishes are likewise required to dry for several hours before continued processing.

Given the fact that oftentimes a number of layers must be produced one over another, the production of an outer corona shield, and especially the production of an overhang corona shield, is a very time-consuming and hence cost-heavy operation.

The problem addressed by the invention is that of enabling a particularly rational production of a corona shield layer for an electric machine.

With respect to a corona shield material—which can be used to produce a corona shield layer—this problem is solved in accordance with the invention through the features of claim 1. Accordingly, the corona shield material comprises a matrix material (also referred to for short hereinafter as “matrix”) which in a preliminary fabriccation state is flowable, i.e., runny or viscous, and which can be cured to a solid in a curing reaction. This matrix material may in particular, on the one hand, consist substantially of monomers which crosslink and/or concatenate in the curing reaction to form the solid. Alternatively, the matrix material may also consist already of partly precrosslinked (bi-stage) polymers, which then crosslink in turn in the curing reaction to form the solid. Such a curing reaction may take place, in particular, by a step-growth polymerization, polyaddition, or polycondensation reaction.

The corona shield material further comprises at least one photosensitive initiator, which is convertible into a reactive state by electromagnetic radiation of a predetermined wave-length range (in particular by ultraviolet (UV) light), in which it is able to trigger the curing reaction. The conversion into the reactive state is also referred to below as “activation” of the initiator. The initiator, in the reactive state, is able in particular to emit reactive species which then trigger the curing reaction. Alternatively the initiator may also itself be in the excited state, whereby it triggers the curing reaction itself.

The corona shield material further comprises at least one filler which is present in particulate form (i.e., in the form of particles, hence as a powder) and which is electrically conductive—that is, either inherently or as a result of a corresponding coating and/or surface treatment, exhibits electrical conductivity. The filler in this case may also be semiconducting or weakly conducting.

The electrical properties of the corona shield material, especially its electrical conductivity, can be influenced sub-stantially through the nature, amount, and grain size distribution of the filler.

An overhang corona shield produced with the corona shield material of the invention preferably has a sheet resistance of between 10⁴ Ω/cm² and 10¹⁴ Ω/cm² (preferably between 10⁸ Ω/cm² and 10¹² Ω/cm²).

An outer corona shield produced with the corona shield material of the invention preferably has a sheet resistance of between 3 Ω/cm² and 20 Ω/cm² in the dry state and 3 kΩ/cm² and 200 kΩ/cm² in the impregnated state.

In brief, the corona shield material of the invention is formed substantially by a matrix material which is curable by means of electromagnetic radiation and which is filled with a conductive or semiconductive, particulate filler.

The radiation to be used for curing may in principle be infra-red, X-ray and/or gamma radiation. In a preferred embodiment, however, the photosensitive initiator can be converted into its reactive state by exposure to UV radiation.

Since the curing of the corona shield material of the invention takes place as a result of irradiation, the corona shield material is able, advantageously, to cure particularly rapidly. The corona shield material here is radiation-curable in spite of its typically comparatively high filler content.

Since, in the case of a typical manufacturing operation of, forexample, a conductor bar provided with an outer or overhang corona shield, the curing of the customary corona shield varnish or impregnating composition is the slowest step in manufacture, a reduction in the cure time produces a substantial acceleration of the overall manufacturing procedure.

Advantageously, through the radiation curing, the time before a subsequent manufacturing step can be reduced to about 180 seconds, for example. In comparison to aforementioned drying times of several hours, therefore, the time spent before manufacturing the overhang corona shield of a generator bar can be reduced from several days, and distribution over a number of operating shifts, to a few minutes.

A further advantage apparent is that normally a photosensitive initiator can be put into its reactive state exclusively by electromagnetic radiation of a predetermined wavelength range, and so a misactivation caused by high temperatures, for example, can be ruled out with comparative reliability.

In preferred embodiments, the curing reaction takes place through a radical crosslinking mechanism, in which, in an initiating reaction, a radical is formed, or by a cationic crosslinking mechanism, in which a cation is formed in the initiating reaction. Found to be particularly advantageous in this context is a cationic crosslinking mechanism, since in that case, in contrast to the radical crosslinking, there is no termination reaction, meaning that, following initial radiation of the material, curing of the matrix is continued even in the shadow region of the filler particles.

In one particularly preferred embodiment, the corona shield material comprises at least two different photosensitive initiators, with each initiator being convertible into its respective reactive state at a wavelength range of the radiation used for activation that is different to the other initiators.

The simultaneous use of a plurality of initiators is advantageous not least on account of the fact that a photo-sensitive initiator is often assigned its own particular wavelength (to be more precise, a defined, spectrally narrow wavelength range), with the initiator being convertible into its reactive state most effectively by radiation from that wavelength range. This wavelength range generally coincides with an absorption maximum of an absorption spectrum of the associated initiator.

For example, the photosensitive initiator 2,4,6-trimethyl-benzoyldiphenylphosphine oxide absorbs radiation in the UV-A range strongly with an absorption maximum at about 370 nm, whereas for radiation at a lower wavelength it is virtually transparent. The photosensitive initiator methyl o-benzoyl-benzoate, in contrast, absorbs in the shorter-wave UV range.

As a result of the aforementioned combination of two or more initiators which can be placed into their reactive state by irradiation at different wavelengths, therefore, depth irradi-ation and depth curing are enabled, with particular advantage. Possible advantageously, therefore, is the curing of relatively thick layers of material of up to one millimeter, whereas, if using an individual initiator, curing of the matrix material might possibly take place only in a near-surface region at such high layer thicknesses.

The concentration of the most reactive initiator is selected in particular to be correspondingly low, so that incident radiation is not entirely absorbed right at the surface of the layer of material.

A preferred initiator concentration is situated at a mass fraction of about 1% initiator, based on the flowable corona shield material (the corona shield material preferably having a solvent-free formulation and hence experiencing only a very small loss in mass in the course of curing). When two or more initiators are being used, this mass fraction is based on the sum total of the individual fractions of the respective initiators.

The irradiation at different wavelengths that is needed for curing is accomplished, in particular, either successively or simultaneously. For example, irradiation takes place by a so-called F-emitter (source with an iron spectrum), G-emitter (source with a gallium spectrum) or H-emitter (source with a mercury spectrum), or by series connection of at least two such emitters.

Having emerged as being preferable for inclusion as photosensitive initiators in the corona shield material are 2,4,6-trimethylbenzoyldiphenylphosphine oxide (TPO), methyl o-benzoylbenzoate (MOBB) and/or bis[4(diphenylsulfonium)phenyl] sulfide bishexafluoroantimonate; the invention, however, is not confined to these initiators.

The corona shield material preferably comprises at least one accelerator (also: synergist or catalyst), which accelerates the curing reaction.

In another preferred embodiment, the corona shield material comprises at least one so-called “secondary accelerator”. This is an accelerator which does not act on the matrix but instead on the initiator, by changing the activation wavelength of the initiator. For this purpose, the accelerator influences the initiator such that the initiator is convertible into its reactive state by radiation having a wavelength that differs from its typical activation wavelength. Additionally or alternatively, a secondary accelerator of this kind may also lower the activation energy for conversion of the initiator into its reactive state.

By means of such a synergist it is possible, advantageously, to force the activation of the initiator at a wavelength which differs from its typical activation wavelength, with the advantageous consequence, especially when two or more initiators are combined, of being able to make effective use of virtually the entire UV spectrum for curing.

In a further embodiment, in addition to the at least one photo-sensitive initiator, there is at least one further, temperature-sensitive initiator present in the corona shield material, this initiator being convertible into its reactive state through a temperature increase. In this embodiment, the corona shield material is endowed advantageously with a so-called “dual cure” option—that is, the curing reaction may be triggered alternatively or additively both by radiation and by a temperature increase.

Additionally or alternatively, the corona shield material preferably comprises a phosphorus compound as additive, more particularly diphenyl cresyl phosphate (preferably in the form of the product Disflamoll® DPK from Lanxess) or dimethyl propanephosphonate (preferably in the form of the product Levagard® DMPP from Lanxess). Using these additives has the advantageous effect of enhancing self-extinction in the event of fire. As a result, the corona shield material may advantageously be made very nonflammable, and may therefore meet “UL-94”, “V-0” or other combustibility restrictions and standards.

Additionally or alternatively, the corona shield material may comprise at least one further additive for influencing the properties of the material. Accordingly, by means of suitable additives, it is possible in particular to adjust advantageously the viscosity of the corona shield material, so that it can be formulated alternatively as a sprayable or a brushable varnish. By this means it is possible advantageously to achieve in an ideal scenario even complete absence of solvent from the corona shield material, thereby qualifying the corona shield material as particularly eco-friendly and benign from the standpoint of health.

Having emerged as being preferred matrix materials are bisphenol A diglycidyl ether, bisphenol F diglycidyl ether, 3,4-epoxycytohexylmethol 3′,4′-epoxycyclohexanecarboxylate (EEC), phenol novolak, acrylate, polyester (especially polyesterimide), urethane and/or enol ethers, it also being possible for the matrix material to consist of a mixture of these substances. The invention, moreover, is not confined to the use of these materials.

An advantageous effect of using a urethanized acrylate as matrix material is the attainment of particularly effective temperature stability for the material. In this way it is possible in particular to achieve a thermal stability classification (TSI) of up to 180° C. In addition, high scratch resistance is achieved.

The filler included in the corona shield material consists in preferred embodiments of silicon carbide particles, graphite particles, carbon black coated mica particles and/or Minatec particles (from Merck). The filler particles preferably have an average grain diameter of 2 to 50 μm, preferably about 10 μm.

In the cured state, the corona shield material in a preferred composition has a filler content of about 50 to 90, preferably about 80 mass percent.

The corona shield material presented is used preferably for producing an outer corona shield and/or an overhang corona shield for an electric machine. The filler present is adapted in a conventional way to the particular end use. In the case of use as OCS, graphite is a preferred filler to include, whereas in the case of use as OHCS, silicon carbide is used in particular.

The use of the corona shield material for producing a corona shield layer is also conceivable, however, in other areas in which a controlled reduction in potential is needed, as for example in the case of a cable end cap or a cable passage.

The corona shield material is used preferably as a varnish or an impregnating composition for impregnating a nonwoven web, the viscosity and the matrix material being selected appropriately for the end use again.

Further provided by the invention is an electric machine, more particularly a powerful motor or generator, which comprises a conductor bar (more particularly of a stator winding) whose principal insulating layer is provided with a corona shield layer. In accordance with the invention, this corona shield layer is produced by applying the above-described corona shield material of the invention and also by curing the material by means of electromagnetic radiation. In its unprocessed state, this corona shield material is again present in the form in particular of a varnish or an impregnating composition.

Exemplary embodiments of the invention are elucidated in more detail below with a drawing. In this drawing:

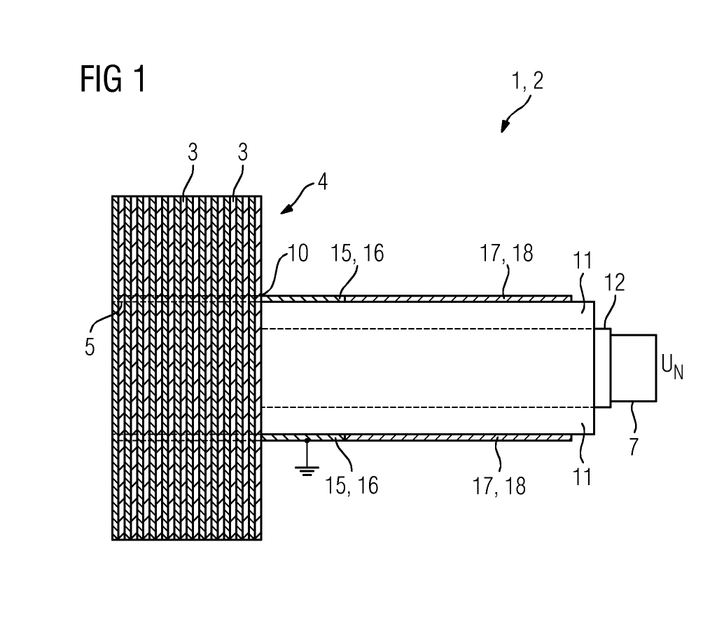

FIG. 1 shows, in a very schematic representation, a detail of an electric machine with an insulated conductor bar, which forms part of a stator winding, the conductor bar having been provided with a corona shield layer consisting of a corona shield material;

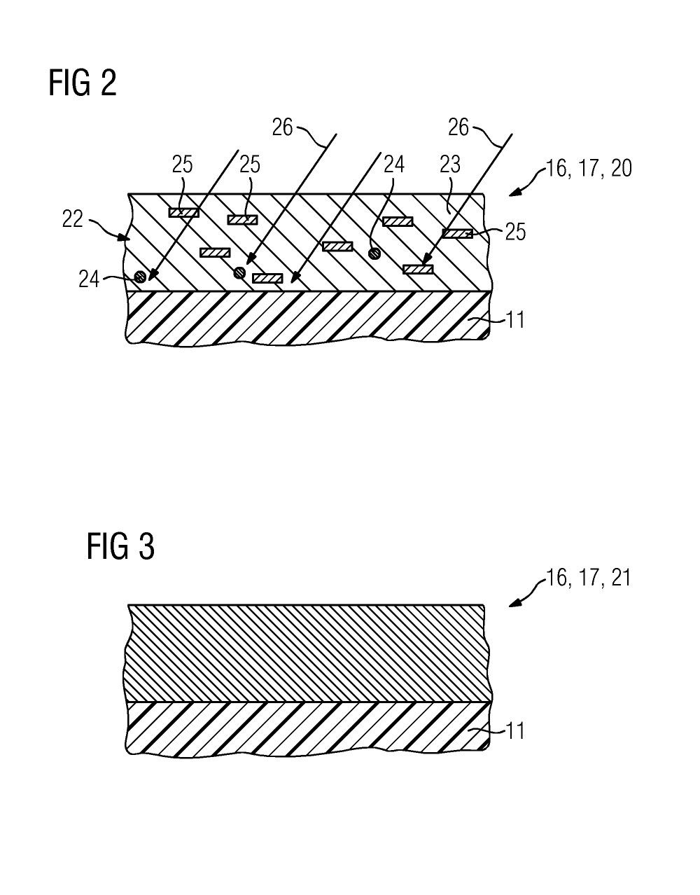

FIG. 2 shows, in a schematic cross section, an outer or overhang corona shield formed from the corona shield layer, in a preliminary fabrication state prior to the curing of the corona shield material; and

FIG. 3 shows, in a representation in accordance with FIG. 2, the outer or overhang corona shield after the curing of the corona shield material.

In all figures, sizes and parts corresponding to one another are always given the same reference symbols.

FIG. 1, in a greatly simplified representation, shows a detail of an electric machine 1, in the present instance an AC turbo-generator. The machine 1 comprises a stator 2, in which a rotor (not shown explicitly) is rotatably mounted.

The stator 2 comprises a (stator) laminate stack 4, which is formed from a multiplicity of lamination plates 3 arranged next to one another in a row and insulated from one another. Made in the laminate stack 4, in a conventional way, transversely to the areal extent of the laminate plates 3, are a plurality of continuous (longitudinal) slots 5, of which, for reasons of simplicity, FIG. 1 shows only one. Lying within each slot 5 is a conductor bar 7. Each conductor bar 7 is formed (in a way which is not shown explicitly) in turn of a plurality of copper conductor elements which are insulated from one another and which are twisted with one another to form a so-called Roebel bar.

The conductor bar 7 protrudes from the slot 5 at a slot exit 10.

In order to insulate the conductor bar 7, which under operating conditions is subjected to a high electrical voltage U_{N}, from the grounded laminate stack 4, it is wrapped peripherally with a fine mica glass fabric tape, impregnated in a vacuum impregnation process, to form a principal insulating layer 11.

In order to avoid the formation of peaks in potential, and hence to reduce the development of partial discharges, the conductor bar 7 is provided, within the principal insulating layer 11, with inner potential grading 12 formed by a conductive nonwoven. Moreover, at least within the laminate stack 4, the principal insulating layer 11 is surrounded on the outside with an electrically conductive layer 15, which serves as outer corona shield 16. The outer corona shield 16 is continued somewhat beyond the slot exit 10, and hence protrudes slightly from the laminate stack 4.

In order to prevent the development of a sliding arrangement, an overhang corona shield 17 is applied to the principal insulating layer 11 in the extension of the outer corona shield 16, said overhang corona shield 17 being formed by a semi-conductive layer 18 whose surface resistance exhibits location-dependent variation in the axial direction of the conductor bar 7.

With reference to FIG. 2 and FIG. 3, the production of the outer corona shield 16 and of the overhang corona shield 17 is elucidated schematically. The outer corona shield 16 and overhang corona shield 17 are each shown in a preliminary fabrication state 20 in FIG. 2, and in an ultimate state 21 in FIG. 3.

To produce the preliminary fabrication state 20, in accordance with FIG. 2, a corona shield material 22 is applied, in an initially viscous state, to the periphery of the principal insulating layer 11. The corona shield material 22 comprises a matrix material 23, a photosensitive initiator 24 (here shown schematically in the form of dots), and a filler 25, which is present in the form of particles, i.e., grains (here shown schematically in the form of bars).

The filler 25 used varies with the specific application. To produce the outer corona shield 16, graphite is used in particular as filler 25, on account of its high conductivity. For the production of the overhang corona shield 17, preference is given to using silicon carbide.

For curing, the corona shield material 21 is exposed to electromagnetic radiation 26, thereby converting the initiator 24 into a reactive state, in which it triggers curing of the matrix material 23. The photosensitive initiator used here is selected such that the radiation 26, absorbed or scattered partially by matrix material 23 and filler 25, is still sufficient, even in the vicinity of the principal insulating layer 11, to activate the initiator 24 and trigger a crosslinking reaction. Consequently (as shown in FIG. 3), in spite of a high filler content of up to about 70 mass percent, through-curing of the entire corona shield material 21 is achieved.

To produce an overhang corona shield 17 or an outer corona shield 16, one possibility is to apply the respective, correspondingly filled viscous corona shield material 22 directly to the principal insulating layer 11. Alternatively, the principal insulating layer 11 may also be first wrapped with an impregnatable fabric tape, which is subsequently impregnated with the corona shield material 22.

In a first variant embodiment, as may be used advantageously particularly for the production of an overhang corona shield, the corona shield material 21 comprises
24 mass % of unsaturated polyesterimide as matrix material 22,
about 1 mass % of trimethylbenzoyldiphenylphosphine oxide (TPO) as photosensitive initiator 23, and
75 mass % of silicon carbide particles with a fineness grade of F600 (having grain sizes in the range of about 3-19 μm) as filler 24.

To produce an overhang corona shield 17, a layer approximately 100 μm thick is applied by coating and is subsequently irradiated with UV light from a G-emitter for 180 s.

Following complete curing, further layers may be applied in the same way.

In a second variant embodiment, useful advantageously particularly for the production of an outer corona shield 16, the corona shield material 21 comprises:
29.7 mass % of bisphenol F diglycidyl ether as matrix material 22,
approximately 0.3 mass % of bis[4(diphenylsulfonium)phenyl] sulfide bishexafluoroantimonate as cationic photosensitive initiator 23,
70 mass % of graphite particles (in the form of carbon black) as filler 24.

In a third variant embodiment, the corona shield material 21 comprises
29 mass % of bisphenol F diglycidyl ether as matrix material 22,
approximately 0.3 mass % of TPO as photosensitive initiator 23,
approximately 0.7 mass % of the cationic thermal initiator available commercially under the brand name “ADEKA OPTON CP-77” (from Adeka), and
70 mass % of graphite particles (in the form of carbon black) as filler 24.

In this variant embodiment, the curing reaction may be triggered both by exposure to ultraviolet radiation and by heating at 80° C. for 1.5 hours.

In one of the abovementioned variant embodiments, the corona shield material 21 is optionally admixed with approximately 0.1 mass % of (mono)ethanolamine as additive, which counteracts the formation of reactive species during the aging of the matrix material 22.

Percentages are always based on the mass of the overall formulation.

Additionally or alternatively to the abovementioned substances, the following in particular may be used as matrix material 22 of the corona shield material 21:
bisphenol A diglycidyl ether (BADGE),
bisphenol F diglycidyl ether (BFDGE),
3,4-epoxycyclohexylmethyl 3′,4′-epoxycyclohexane-carboxylate (ECC),
phenol novolak,
an acrylate,
a urethane and/or
an enol ether.

1. A corona shield material for producing a corona shield layer for an electric machine, the shield material comprising:
an initially flowable matrix material which has the capability to be cured to a solid in a curing reaction;
a photosensitive initiator in the matrix material and which has the capability to be converted by electromagnetic radiation into a reactive state triggering the curing reaction; and
at least one electrically conducting filler present in particulate form in the matrix material.

2. The corona shield material as claimed in claim 1, wherein the photosensitive initiator has the capability to be convertible into its reactive state through use of ultraviolet radiation on the matrix material.

3. The corona shield material as claimed in claim 1, wherein the matrix material is curable in a radical or cationic crosslinking mechanism.

4. The corona shield material as claimed in claim 2, which comprises at least two of the photosensitive initiators, wherein each initiator is convertible into its respective reactive state at a respective wavelength range of the radiation used for the activation that is different from the respective wavelength ranges of the radiation used for the other initiators.

5. The corona shield material as claimed in claim 1, wherein the initiator comprises:
2,4,6-trimethylbenzoyldiphenylphosphine oxide (TPO), methyl o-benzoylbenzoate (MOBB); and/or
bis[4(diphenylsulfonium)phenyl] sulfide bishexafluoroantimonate).

6. The corona shield material as claimed in claim 1, wherein the initiator has a mass fraction of about 1% in the flowable state of the corona shield material.

7. The corona shield material as claimed in claim 1, further comprising at least one accelerator having such a composition as to be operable to accelerate the curing reaction.

8. The corona shield material as claimed in claim 1, further comprising at least one accelerator having such a composition as to be operable to change an activation wavelength of the initiator.

9. The corona shield material as claimed in claim 1, further comprising a further temperature-sensitive initiator which is convertible into its reactive state by a temperature increase of the temperature-sensitive initiator.

10. The corona shield material as claimed in claim 1, further comprising a phosphorus compound additive.

11. The corona shield material as claimed in claim 1, wherein the matrix material comprises at least one of:
bisphenol A diglycidyl ether;
bisphenol F diglycidyl ether;
3,4-epoxycyclohexylmethyl 3′,4′-epoxycyclohexanecarboxylate;
phenol novolak;
an acrylate;
a urethane; and
an enol ether.

12. The corona shield material as claimed in claim 1, wherein the filler comprises at least one of:
silicon carbide particles;
graphite particles;
carbon black;
coated mica particles; and
Minatec particles.

13. The corona shield material as claimed in claim 1, wherein particles of the particulate form filler have an average grain diameter of 2 to 50 μm.

14. The corona shield material as claimed in claim 1, wherein in its cured state, the filler has a filler content of about 50 to 90 mass % particulate form of the shield material.

15. An outer corona shield and/or an overhang corona shield for an electric machine comprised of a corona shield material as claimed claim 1.

16. A corona shield material as claimed in claim 1, in a form of a varnish or as an impregnating composition applied to an insulating layer on a conductor.

17. An electric machine having a conductor bar, a principal insulating layer on the conductive bar;
a corona shield layer on the conductive bar, the corona shield layer having been produced by applying the corona shield material as claimed in claim 1 and the corona shield material having been cured by means of electromagnetic radiation on the material.

18. The corona shield material as claimed in claim 1, wherein the initiator comprises:
2,4,6-trimethylbenzoyldiphenylphosphine oxide (TPO), methyl o-benzoylbenzoate (MOBB);
bis[4(diphenylsulfonium)phenyl] sulfide bishexafluoroantimonate);
the matrix material comprises at least one of:
bisphenol A diglycidyl ether;
bisphenol F diglycidyl ether;
3,4-epoxycyclohexylmethyl 3′,4′-epoxycyclohexanecarboxylate;
phenol novolak;
an acrylate;
a urethane;
an enol ether; and
the filler comprises at least one of:
silicon carbide particles;
graphite particles;
carbon black;
coated mica particles; and
Minatec particles.
